(19) United States
(12) Patent Application Publication
(10) Pub. No.: US 2025/0329560 A1
(43) Pub. Date: Oct. 23, 2025

(54) AUTOMATED MACHINE LEARNING WAFERLESS CHAMBER CONDITIONING PROCESS FOR THERMAL SEMICONDUCTOR PROCESS CHAMBERS

(71) Applicant: Applied Materials, Inc., Santa Clara, CA (US)

(72) Inventors: Martin A. HILKENE, Gilroy, CA (US); Amritha RAMMOHAN, Santa Clara, CA (US); Yunil CHO, Santa Clara, CA (US)

(21) Appl. No.: 18/640,194

(22) Filed: Apr. 19, 2024

(51) Int. Cl. H01L 21/67; G05B 13/02

(52) U.S. Cl. CPC H01L 21/67248; G05B 13/0265

(57) ABSTRACT

Methods and devices for automatically conditioning a processing chamber are disclosed herein. Embodiments include determining a high chamber temperature value and a low chamber temperature value based on measuring temperatures associated with the chamber, wherein: the high chamber temperature value is determined based on detecting a peak temperature value associated with the chamber during substrate processing; and the low chamber temperature value is determined based on detecting a minimum temperature value associated with the chamber during the substrate processing. Embodiments further include heating the chamber until a detected temperature associated with the chamber reaches the high chamber temperature value. Embodiments further include cooling the chamber until a corresponding detected temperature associated with the chamber reaches the low chamber temperature value.

### BACKGROUND

### Field

Embodiments of the present disclosure generally relate to semiconductor processing and, more specifically, to an automated machine learning-based process for conditioning of a substrate processing chamber according to measured optimum processing chamber conditions.

### Description of the Related Art

Semiconductor substrates are processed for a wide variety of applications, including the fabrication of integrated devices and microdevices. One method of processing substrates includes growing an oxide layer on an upper surface of the substrate within a processing chamber. The oxide layer may be deposited by exposing the substrate to oxygen and hydrogen gases while heating the substrate with a radiant heat source. The oxygen radicals strike the surface of the substrate to form a layer, for example a silicon dioxide layer, on a silicon substrate.

Before a substrate processing chamber can be used to process substrates, the processing chamber is generally pre-heated. Pre-heating a processing chamber removes contaminants from the chamber that may cause impurities in processed substrates. Additionally, the pre-heating process allows the processing chamber to reach a stable state that can be maintained throughout processing. The inside of a chamber may be heated to an optimal temperature for processing substrates, but components associated with the chamber may not reach a stable state until the inside of the chamber has been heated to the optimal temperature for a certain period of time. For example, parts of the chamber or components of the chamber may continue to absorb heat until these parts and components reach a certain temperature. Processing a substrate before the components of the chamber reach a stable state may result in imperfections in the substrates because of fluctuations in temperature that occur due to the components absorbing heat. Existing techniques for pre-heating processing chambers involve processing “dummy” substrates (e.g., substrates that are used solely for pre-heating the chamber and are later discarded) in order to replicate the conditions of substrate processing and thus allow the chamber to reach a stable condition for a given processing recipe. Repeatedly cycling dummy substrates into and out of a chamber while heating both the chamber and the substrates involves an extensive amount of time and resources. For example, opening the chamber, removing a substrate, inserting another substrate, sealing the chamber, and then repeating the process until thermal stability is reached can add several minutes onto each processing run. Also, heating dummy substrates that are later discarded amounts to a waste of the thermal energy used to heat the substrate. However, conventional chamber conditioning techniques are not generally able to replicate processing conditions without cycling dummy substrates.

Therefore, there is a need for improved processing chamber conditioning techniques that provide for more efficient and accurate chamber conditioning.

### SUMMARY

Embodiments described herein generally relate to conditioning a substrate processing chamber, and more particularly, to automatically detecting optimal processing chamber conditions through a machine learning-based process and replicating these conditions through a pre-heating process.

In one embodiment, a method comprises determining a high chamber temperature value and a low chamber temperature value based on measuring temperatures associated with the chamber, wherein: the high chamber temperature value is determined based on detecting a peak temperature value associated with the chamber during substrate processing; and the low chamber temperature value is determined based on detecting a minimum temperature value associated with the chamber during the substrate processing; heating the chamber until a detected temperature associated with the chamber reaches the high chamber temperature value; and cooling the chamber until a corresponding detected temperature associated with the chamber reaches the low chamber temperature value.

In another embodiment, a self-conditioning substrate processing chamber comprises a processing chamber for processing substrates; a heating element configured to heat the chamber and allow the chamber to cool; one or more temperature measurement devices for measuring the temperature associated with the processing chamber; and a computing device capable of: determining a high chamber temperature value and a low chamber temperature value based on measuring temperatures associated with the chamber, wherein: the high chamber temperature value is determined based on detecting a peak temperature value associated with the chamber during substrate processing; and the low chamber temperature value is determined based on detecting a minimum temperature value associated with the chamber during the substrate processing; causing the heating element to heat the chamber until a detected temperature associated with the chamber reaches the high chamber temperature value; and causing the heating element to let the chamber cool until a corresponding detected temperature associated with the chamber reaches the low chamber temperature value.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 depicts an example substrate processing system according to certain embodiments.

FIG. 2 depicts an example of temperature sensor measurements associated with a substrate processing system according to certain embodiments.

FIG. 3 is a flow diagram of example operations for automatically conditioning a substrate processing chamber, according to certain embodiments

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to automatically conditioning a substrate processing chamber for processing substrates, such as silicon wafers. More particularly, embodiments described herein provide devices and methods for automatically conditioning a substrate processing chamber.

Embodiments described herein provide a machine learning based process for determining optimal processing chamber conditions during substrate processing. The processing chamber may be configured based on the determined optimal conditions, allowing for automatically conditioning the chamber without cycling substrates into and out of the chamber. Removing the need to cycle substrates during chamber conditioning saves a substantial amount of time and resources.

Embodiments described herein incorporate sensors designed to measure the conditions, such as temperature, inside a processing chamber. While the chamber is being pre-heated for substrate processing (e.g., by a process involving cycling substrates into and out of the chamber) or during substrate processing, a temperature associated with the chamber may be recorded with respect to time. The measured temperature may be, for example, the temperature of a component associated with the chamber. The measured temperature may be lower at the start of cycling substrates, and then gradually increase as the component absorbs more heat. After cycling a particular number of substrates, the chamber may absorb enough heat to reach a stable state. Once in this stable state, the temperature of the component may oscillate between a minimum temperature (e.g., a temperature reached when the chamber is opened to remove a substrate) and a peak temperature (e.g., a temperature reached before opening the chamber to remove a substrate). The peak value and the minimum value may be determined based on the temperature measured by the sensors. The determination of the peak and minimum values may be further based on the temperature remaining within a consistent range during oscillation, indicating that the chamber has reached a stable state. After determining the peak and minimum values, the chamber may be heated until the temperature measured by the sensor reaches the peak value and cooled until the temperature measured by the sensor reaches the minimum value. The heating and cooling may be repeated to ensure that the chamber has reached a stable state. Thus, once the peak and minimum temperatures are determined, the processing chamber may be conditioned without further substrate cycling.

### Example Self-Conditioning Substrate Processing Chamber

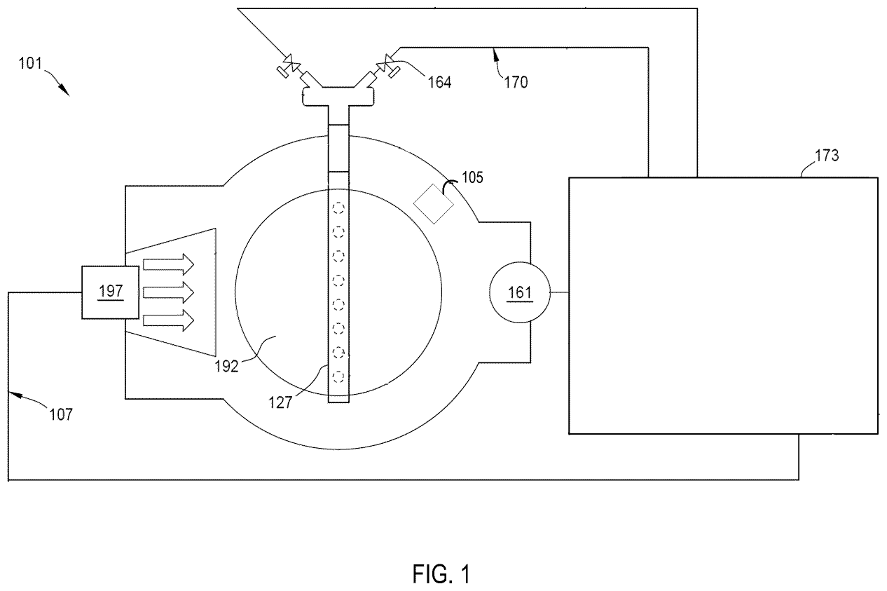

FIG. 1 is a schematic partial top view of a self-conditioning processing chamber system 101, according to one implementation. A control module 173 may control various components associated with the processing chamber system 101. The control module 173 may comprise one or more processors configured to control the chamber system 101. For example, the control module 173 may have a connection 107 to a heater 197. For example, the heater 197 may be a lamp that the control module 173 can turn on and off to control the temperature of the processing chamber 192, although other types of heater systems are contemplated. One or more supply paths 170 may supply processing gases to the chamber 192. The control module 173 may control one or more supply valves 164 that control the flow of processing gasses into the chamber 192 through a supply duct 127. Thus, control module 173 may increase the pressure of the chamber and control the flow of gasses into the chamber. The control module 173 may control a gas outlet 161. The gas outlet 161 may allow for expelling gas from the chamber 192, thus enabling the control module 173 to control the pressure inside the chamber 192. One or more sensors 105 may measure the temperature of the chamber 192 or the temperature of components associated with the chamber 192. The control module 173 may also control the insertion of substrates into the chamber 192 and the removal of substrates from the chamber 192.

Before processing substrates inside the chamber 192, it is necessary to first condition the chamber 192 by pre-heating the chamber 192. Pre-heating the chamber 192 removes contaminants from the chamber 192 (e.g., by burning off the contaminants or causing the contaminants to evaporate). If not removed, these contaminants may result in substrates that contain impurities.

Pre-heating the chamber 192 also causes the components of the chamber 192 to reach a stable thermal state. For example, a conventional pre-heating procedure for a given substrate processing recipe may comprise heating a given number of substrates in the chamber 192 according to the processing recipe (i.e., the substrates are heated to a temperature specified by the processing recipe for an amount of time specified by the recipe). Substrates that are heated during the pre-heating procedure may contain imperfections due to fluctuations in temperature caused by components of the chamber 192 absorbing heat. For example, before the pre-heating process begins (e.g., at start-up or after preventative maintenance has been performed), the chamber 192 and its associated components may be cool. Once the pre-heating process begins, a substrate may be heated according to a recipe, but the chamber 192 and various components of the chamber 192 may continue to absorb heat until multiple substrates have been heated and cycled out of the chamber 192.

During pre-heating, before the chamber 192 is opened to remove a substrate, the temperature of the chamber 192 and/or various components of the chamber 192 may reach a peak value. When the chamber 192 is opened to remove a substrate, the temperature of the chamber 192 and/or various components of the chamber 192 may decrease before increasing again once another substrate is inserted and the chamber 192 is closed. After several substrates have been heated inside the chamber 192 during the pre-heating procedure, the temperature of the chamber 192 and/or various components of the chamber 192 may begin to stay within a given range. This may indicate that the chamber 192 and/or various components of the chamber 192 have reached a stable thermal state and are no longer absorbing heat. For example, the minimum temperature value after the chamber 192 is opened may remain within a threshold as substrates are cycled during the pre-heating procedure. Also, the peak temperature value may remain within a threshold as substrates are cycled during the pre-heating procedure.

In certain embodiments of the present disclosure, a conventional pre-heating procedure is performed for a given substrate processing recipe and/or substrates are processed according to the recipe. As discussed below, the conventional pre-heating process and/or the processing of substrates according to the processing recipe are used as part of a self-training process to train the chamber system 101 to condition itself for the processing recipe. During this self-training process, a heating cycle may be performed in which a substrate may be inserted into the chamber 192, the chamber 192 may be sealed and the substrate may be heated inside the chamber 192, and then the chamber may be opened and the substrate may be removed from the chamber 192. Then, the heating cycle may be repeated with another substrate. The temperature of the chamber 192 (or the temperature of a component associated with the chamber 192) may be measured by sensor 105 and recorded throughout the self-training process. The control module 173 may be configured to evaluate the recorded temperature measurements and detect peaks and minimums of the temperature measurements. In some embodiments, the heating cycle is repeated until the control module 173 detects that the peak temperature and/or the minimum temperature have remained within a threshold range (e.g., a training threshold range) for a given number of heating cycles. For example, the threshold range may be 0.5 degrees Celsius (included as an example, and other ranges are possible). In certain embodiments, the threshold range for the peak value is a different size than the threshold range for the minimum value. After the minimum and peak temperatures have been determined to have stayed within a threshold range for the given number of heating cycles, the control module 173 may determine a high chamber temperature value based on the peak temperature value and a low chamber temperature value based on the minimum temperature value. For example, if the peak temperature remains at a particular value (+/− a threshold amount, e.g. one degree Celsius) for the given number of heating cycles, the high chamber temperature value may be set at the peak temperature value (+/− the threshold amount). As another example, if the minimum temperature remains at a particular value (+/− a threshold amount) for the threshold number of heating cycles, the low chamber temperature value may be set at the minimum temperature value (+/− the threshold amount). As an example, the threshold number of heating cycles may be four.

Certain embodiments provide that the heating cycle is repeated for a given number of iterations. For example, a user may specify a number of substrates to be cycled during the self-training process, and the specified number of substrates may be inserted into the chamber 192, heated, and removed from the chamber 192. The peak temperature value measured during the self-training process may be selected as the high chamber temperature value (+/− a threshold amount). The minimum temperature value measured during the self-training process after a particular number of heating cycles are completed may be selected as the low chamber temperature value (+/− a threshold amount).

According to certain embodiments, other conditions inside the chamber 192 may be measured during the self-training process. For example, the pressure inside the chamber 192 may be measured (e.g., by a pressure sensor), and when the chamber is determined to have reached thermal stability (i.e., the peak and minimum values remain within the threshold, as described above), this measured pressure may be selected as the thermal stability pressure. As discussed below, the pressure of the chamber may be set to the thermal stability pressure during the self-conditioning process. Other chamber metrics may be recorded during the self-training process. For example, the rate of gas flow measured when the chamber 192 reaches thermal stability may be selected as the thermal stability rate of flow, and the rate of gas flow for the chamber 192 during the self-conditioning process may be set to the thermal stability rate of flow.

Selecting the high chamber temperature value and the low chamber temperature value may mark the end of the self-training process for the self-conditioning processing chamber system 101. After the self-training is complete, the self-conditioning processing chamber system 101 may then begin the self-conditioning process (i.e., the chamber system 101 conditions itself based on the high chamber temperature value and the low chamber temperature value). The self-training and self-conditioning processes effectively amount to a rules-based machine learning process. This machine learning process involves training the chamber system 101 based on a given processing recipe (i.e., substrates are heated to a temperature specified by the processing recipe during pre-heating or during processing, and the high and low chamber temperature values are set based on an indication that thermal stability has been reached). Then, the trained chamber system 101 may condition itself for the given processing recipe. In some embodiments, thermal stability metrics (e.g., high chamber temperature value, low chamber temperature value, thermal stability pressure, and/or thermal stability rate of flow) for one or more processing recipes are stored by control module 173. A user may select a given processing recipe, and the chamber system 101 may be automatically conditioned based on the thermal stability metrics for that recipe determined during the self-training process, as discussed below.

In the self-conditioning process, the chamber 192 is heated until the temperature measured by the sensor 105 reaches the high chamber temperature value (+/− a threshold amount, e.g., a conditioning threshold of variance). Then, the chamber 192 may be cooled until the temperature measured by the sensor 105 reaches the low chamber temperature value (+/− a threshold amount). The control module 173 may perform the heating by turning on lamp 197 and allowing the temperature measured by sensor 105 to increase. The control module 173 may perform the cooling by turning off lamp 197 and allowing the temperature measured by sensor 105 to decrease. In some embodiments, the heating and the cooling may be repeated for a given number of iterations. Certain embodiments provide that the heating and the cooling are repeated until the peak and/or minimum temperatures measured by sensor 105 remain within a threshold range of the high chamber temperature value and the low chamber temperature value respectively for a threshold number of iterations. Some embodiments provide that during the self-conditioning process, the control module 173 adjusts the pressure inside the chamber 192 to the thermal stability pressure determined during the self-training process. According to certain embodiments, the control module 173 adjusts the rate of gas flow inside the chamber 192 to the thermal stability rate of flow determined during the self-training process. The control module 173 may adjust the pressure inside the chamber 192 and/or the rate of gas flow inside the chamber 192 by adjusting supply value 164. The control module 173 may also adjust the pressure inside the chamber 192 by expelling gas from the chamber 192 via gas outlet 161. By performing the self-conditioning process described above, the chamber conditions associated with a given processing recipe may be replicated without the need for cycling dummy substrates during pre-heating.

According to some embodiments, the self-conditioning process may be started automatically based on a measured temperature associated with the chamber 192 falling below a certain level. For example, if substrate processing is halted or if a temperature associated with the chamber 192 otherwise falls, the chamber 192 may no longer be thermally stable. Automatically triggering the self-conditioning process may prevent substrates from being processed inside a chamber that is not thermally stable.

Example Temperature Sensor Measurements Associated with a Substrate Processing System According to Certain Embodiments

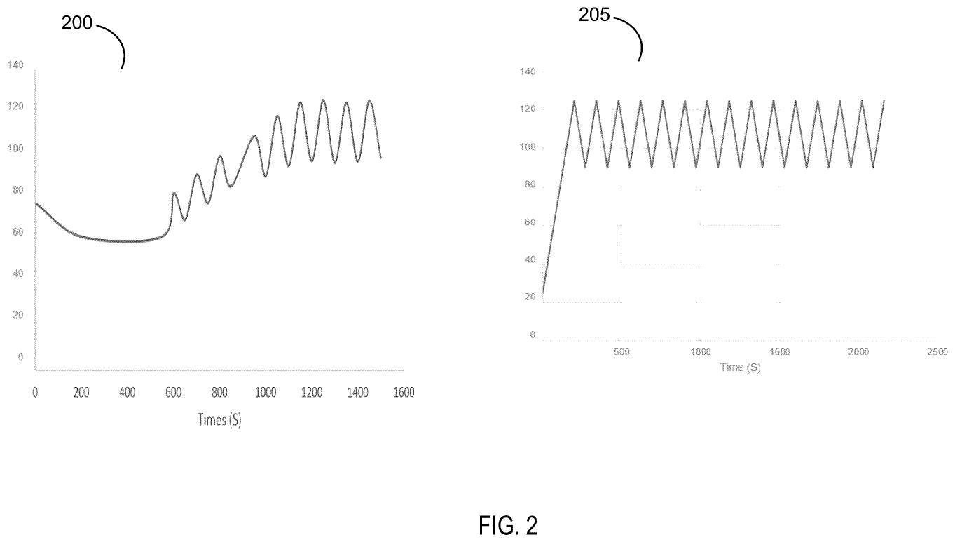

FIG. 2 illustrates example temperature sensor measurements associated with a substrate processing system according to certain embodiments.

200 shows an example view of temperature sensor measurements during a conventional pre-heating process that may be used to train the self-conditioning chamber system. The X axis of the graph shows time, and the Y axis of the graph shows temperature measured in Celsius. The temperature may be a temperature measured by a sensor placed on the chamber or on a component associated with the chamber. The temperature steadily decreases following a prior round of substrate processing. At approximately 500 seconds, the conventional pre-heating process begins. A “dummy” substrate is heated to a temperature specified by the processing recipe (for example, 800 degrees Celsius). As this substrate is being heated, the temperature measured by the sensor increases to approximately eighty degrees Celsius. For example, this may indicate that the component or the outside of the chamber is gaining heat. The measured temperature drops to approximately seventy degrees Celsius once the chamber is opened and the first dummy substrate is removed. Another substrate is heated and this time the measured temperature increases to approximately ninety degrees Celsius. After multiple dummy substrates have been cycled into and out of the chamber, the peaks and minimums of the measured temperature begin to consistently remain at approximately one hundred and twenty-five degrees Celsius and ninety degrees Celsius respectively. This indicates that the chamber has reached thermal stability. The processing chamber system may detect that the peak and minimum values remained within a threshold range for a threshold number of iterations. For example, the threshold range may be +/− one degree Celsius and the threshold number of iterations may be three. In this example, both the peak and minimum values remained within three degrees Celsius of the prior peaks and minimums for at least three iterations. Based on the measured values remaining within the threshold, the chamber system may set the high chamber temperature value to one hundred and twenty-five degrees Celsius and the low chamber temperature value to ninety degrees Celsius.

205 shows an example view of temperature sensor measurements during the self-conditioning process. The chamber is heated until the temperature measured by the sensor reaches the high chamber temperature value. Then then chamber is allowed to cool until the temperature measured by the sensor reaches the low chamber temperature value. Then, the heating and cooling are repeated for several iterations to ensure that the chamber has reached thermal stability.

### Example Operations for Automatically Conditioning a Substrate Processing Chamber

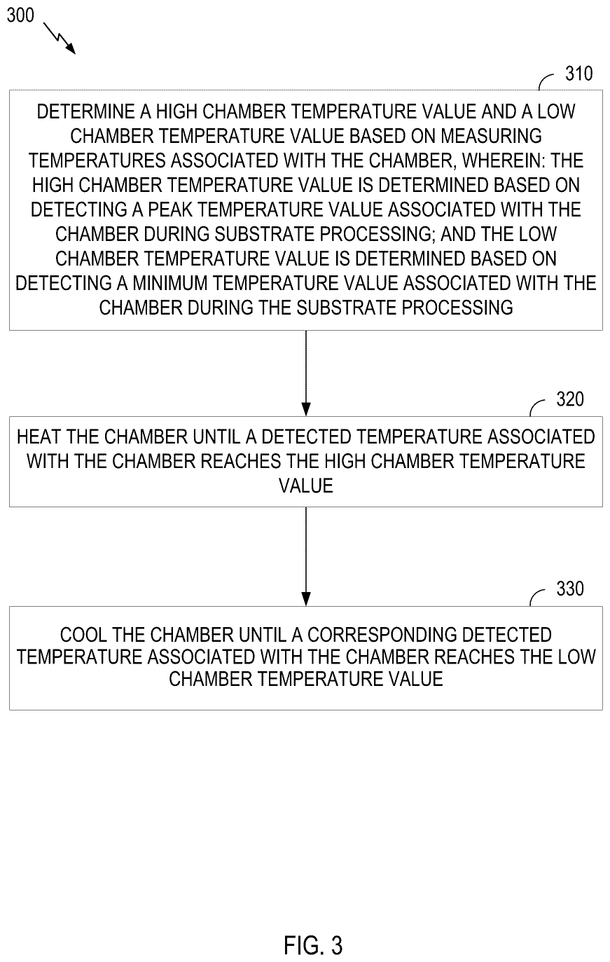

FIG. 3 is a flow diagram of example operations 300 for automatically conditioning a substrate processing chamber. Operations 300 may be performed by a computing device comprising one or more processors, such as the computing device as discussed with respect to FIG. 1.

Operations 300 begin at 310, with determining a high chamber temperature value and a low chamber temperature value based on measuring temperatures associated with the chamber, wherein: the high chamber temperature value is determined based on detecting a peak temperature value associated with the chamber during substrate processing; and the low chamber temperature value is determined based on detecting a minimum temperature value associated with the chamber during the substrate processing. In some embodiments, determining the high chamber temperature value and determining the low chamber temperature value are based on successively heating substrates in the chamber until temperature values associated with the chamber stay within a training threshold of variance. Certain embodiments provide that determining the high chamber temperature value is based on a peak measured temperature value associated with the chamber that is within the training threshold of variance. According to some embodiments, determining the low chamber temperature value is based on a minimum measured temperature value associated with the chamber that is within the training threshold of variance. Some embodiments provide that determining the high chamber temperature value and determining the low chamber temperature value are based on successively heating a given number of substrates in the chamber. In certain embodiments, the high chamber temperature value is selected based on detecting a peak temperature value associated with the chamber in connection with processing a given number of substrates. According to certain embodiments, the low chamber temperature value is selected based on detecting a minimum temperature value associated with the chamber after a given number of substrates have been processed.

Operations 300 continue at 320, with heating the chamber until a detected temperature associated with the chamber reaches the high chamber temperature value.

Operations 300 continue at 330, with cooling the chamber until a corresponding detected temperature associated with the chamber reaches the low chamber temperature value. Certain embodiments provide that the heating and the cooling are repeated for a given number of iterations. In some embodiments, the heating and the cooling are repeated until detected temperature values associated with the chamber stay within a conditioning threshold of variance. According to some embodiments, the heating and the cooling are repeated until a peak detected temperature value associated with the chamber stays within the conditioning threshold of variance. Some embodiments provide that the heating and the cooling are repeated until a minimum detected temperature value associated with the chamber stays within the conditioning threshold of variance.

According to certain embodiments, a pressure value associated with the chamber is selected based on measuring a pressure inside the chamber when temperature values associated with the chamber remain within a given range, wherein the pressure of the chamber is set to the selected pressure value during the heating and the cooling.

Some embodiments provide that the substrate processing is performed according to multiple substrate processing recipes, wherein a respective high chamber temperature value and a respective low chamber temperature value are determined for each recipe.

While the foregoing is directed to implementations of the present disclosure, other and further implementations of the disclosure may be devised without departing from the basic scope thereof, and the scope thereof is determined by the claims that follow.

What is claimed is:

1. A method for machine learning based automated conditioning of a substrate processing chamber according to measured optimum processing chamber conditions, comprising:
determining a high chamber temperature value and a low chamber temperature value based on measuring temperatures associated with the chamber, wherein:
the high chamber temperature value is determined based on detecting a peak temperature value associated with the chamber during substrate processing; and
the low chamber temperature value is determined based on detecting a minimum temperature value associated with the chamber during the substrate processing;
heating the chamber until a detected temperature associated with the chamber reaches the high chamber temperature value; and
cooling the chamber until a corresponding detected temperature associated with the chamber reaches the low chamber temperature value.

2. The method of claim 1, wherein determining the high chamber temperature value and determining the low chamber temperature value are based on successively heating substrates in the chamber until temperature values associated with the chamber stay within a training threshold of variance.

3. The method of claim 2, wherein determining the high chamber temperature value is based on a peak measured temperature value associated with the chamber that is within the training threshold of variance.

4. The method of claim 2, wherein determining the low chamber temperature value is based on a minimum measured temperature value associated with the chamber that is within the training threshold of variance.

5. The method of claim 1, wherein determining the high chamber temperature value and determining the low chamber temperature value are based on successively heating a given number of substrates in the chamber.

6. The method of claim 5, wherein the high chamber temperature value is selected based on detecting a peak temperature value associated with the chamber in connection with processing a given number of substrates.

7. The method of claim 5, wherein the low chamber temperature value is selected based on detecting a minimum temperature value associated with the chamber after a given number of substrates have been processed.

8. The method of claim 1, wherein the heating and the cooling are repeated for a given number of iterations.

9. The method of claim 1, wherein the heating and the cooling are repeated until detected temperature values associated with the chamber stay within a conditioning threshold of variance.

10. The method of claim 9, wherein the heating and the cooling are repeated until a peak detected temperature value associated with the chamber stays within the conditioning threshold of variance.

11. The method of claim 9, wherein the heating and the cooling are repeated until a minimum detected temperature value associated with the chamber stays within the conditioning threshold of variance.

12. The method of claim 1, wherein a pressure value associated with the chamber is selected based on measuring a pressure inside the chamber when temperature values associated with the chamber remain within a given range, wherein the pressure of the chamber is set to the selected pressure value during the heating and the cooling.

13. The method of claim 1, wherein the substrate processing is performed according to multiple substrate processing recipes, wherein a respective high chamber temperature value and a respective low chamber temperature value are determined for each recipe.

14. A self-conditioning substrate processing chamber, comprising:
a processing chamber for processing substrates;
a heating element configured to heat the chamber and allow the chamber to cool;
one or more temperature measurement devices for measuring the temperature associated with the processing chamber; and
a computing device capable of:
determining a high chamber temperature value and a low chamber temperature value based on measuring temperatures associated with the chamber, wherein:
the high chamber temperature value is determined based on detecting a peak temperature value associated with the chamber during substrate processing; and
the low chamber temperature value is determined based on detecting a minimum temperature value associated with the chamber during the substrate processing;
causing the heating element to heat the chamber until a detected temperature associated with the chamber reaches the high chamber temperature value; and
causing the heating element to let the chamber cool until a corresponding detected temperature associated with the chamber reaches the low chamber temperature value.

15. The self-conditioning substrate processing chamber of claim 14, wherein the computing device is configured to cause the heating element to heat the chamber to the high chamber temperature and allow the chamber to cool to the low chamber temperature for a given number of iterations.

16. The self-conditioning substrate processing chamber of claim 14, wherein the computing device is configured to cause the heating element to heat the chamber to the high chamber temperature and allow the chamber to cool to the low chamber temperature until temperature values associated with the chamber stay within a conditioning threshold of variance.

17. The self-conditioning substrate processing chamber of claim 14, wherein the computing device is configured to determine the high chamber temperature value based on successively heating substrates in the chamber and detecting a peak measured temperature value associated with the chamber that is within a training threshold of variance.

18. The self-conditioning substrate processing chamber of claim 14, wherein the computing device is configured to determine the low chamber temperature value based on successively heating substrates in the chamber and detecting a minimum measured temperature value associated with the chamber that is within a training threshold of variance.

19. The self-conditioning substrate processing chamber of claim 14, wherein the computing device is configured to determine the low chamber temperature value based on detecting a minimum temperature value associated with the chamber after a given number of substrates have been processed.

20. The self-conditioning substrate processing chamber of claim 14, further comprising a pressure sensor configured to measure a pressure inside the chamber, wherein a pressure value associated with the chamber is selected based on measuring the pressure inside the chamber when temperature values associated with the chamber remain within a given range, wherein the computing device is configured to adjust the pressure of the chamber to the selected pressure value.
